(19) United States
(12) Patent Application Publication
(10) Pub. No.: US 2026/0331433 A1
(43) Pub. Date: Oct. 22, 2026

(54) SUBSTRATE PROCESSING APPARATUS

(71) Applicant: Tokyo Electron Limited, Tokyo (JP)

(72) Inventors: Ryoji BAMBA, Miyagi (JP); Takashi TAIRA, Miyagi (JP)

(73) Assignee: Tokyo Electron Limited, Tokyo (JP)

(21) Appl. No.: 19/701,823

(22) Filed: Jun. 9, 2026

Related U.S. Application Data
(63) Continuation of application No. PCT/JP2025/004301, filed on Feb. 10, 2025.

(30) Foreign Application Priority Data
Feb. 22, 2024 (JP) 2024-025695

(51) Int. Cl. H01J 37/32; H10P 72/00

(52) U.S. Cl. CPC H01J 37/32633; H01J 37/32651; H01J 37/32715; H10P 72/0421; H01J 2237/334

(57) ABSTRACT

A substrate processing apparatus has a chamber having an opening, a shutter mechanism to open and close the opening, a substrate support, and a baffle plate. The shutter mechanism includes: a valve body; a first electrically conductive surface at a lower portion of the valve body; a second electrically conductive surface at an upper portion of the valve body; a plurality of electrically conductive members on the first and second electrically conductive surfaces; and two or more lifting/lowering mechanisms. In a case where the opening has been closed, the first and second electrically conductive surfaces come into contact with the baffle plate and an upper member of an upper portion of the chamber, respectively, in a vertical direction and becomes electrically continuous with the baffle plate and the upper member of the upper portion of the chamber by means of the electrically conductive members.

### CROSS-REFERENCE TO RELATED APPLICATIONS

This application is a continuation application of International Application PCT/JP2025/004301, filed on Feb. 10, 2025, and designating the U.S., which claims priority to Japanese Patent Application No. 2024-025695, filed on Feb. 22, 2024, the entire contents of each are incorporated herein by reference.

### FIELD

The present disclosure relates to a substrate processing apparatus.

### BACKGROUND

A substrate processing apparatus disclosed in Patent Literature 1 includes: a cylindrical chamber having an opening for carrying in a substrate to be processed; a deposition shield arranged along an inner wall of the chamber and having an opening at a position corresponding to the opening of the chamber; and a plate-shaped shutter to open and close the opening of the deposition shield.
Patent Literature 1: Japanese Laid-open Patent Publication No. 2015-126197

### SUMMARY

According to an aspect of a present disclosure, there is provided a substrate processing apparatus, wherein the substrate processing apparatus includes: a chamber that is cylindrical and is configured to have at least one opening; a shutter mechanism configured to open and close the opening; a substrate support configured to support a substrate; and a baffle plate configured to be provided between the substrate support and the shutter mechanism, the shutter mechanism including: a valve body having a length that is half of the inner circumference of the chamber or longer; a first electrically conductive surface that is provided on a lower portion of the valve body and comes into contact with a reverse face of the baffle plate; a second electrically conductive surface that is provided on an upper portion of the valve body and comes into contact with an upper member that is provided along an inner wall of an upper portion of the chamber, the upper member being electrically conductive; electrically conductive members that are arc-shaped or ring-shaped and are respectively arranged in grooves that are respectively provided on the first electrically conductive surface and the second electrically conductive surface, the grooves being arc-shaped or ring-shaped; and two or more lifting/lowering mechanisms that are connected to the lower portion of the valve body and lift and lower the valve body, in a case where the valve body is lifted and the opening is closed, the first electrically conductive surface comes into contact with the reverse face of the baffle plate in a vertical direction and becomes electrically continuous with the reverse face of the baffle plate by means of the electrically conductive members, and in the case where the valve body is lifted and the opening is closed, the second electrically conductive surface comes into contact with the upper member in the vertical direction and becomes electrically continuous with the upper member by means of the electrically conductive members.

### BRIEF DESCRIPTION OF DRAWINGS

FIG. 1 is a schematic plan view of an example of a substrate processing system in an embodiment of the present disclosure.

FIG. 2 is a diagram illustrating an example of a plasma processing system in an embodiment of the present disclosure.

FIG. 3 is a perspective view of an example of a shutter mechanism in the embodiments.

FIG. 4 is a partial enlarged view of an example of a cross section of a valve body of the shutter mechanism in the embodiments.

FIG. 5 is a partial enlarged view of an example of a cross section in a state where the shutter mechanism has been closed, in the embodiments.

FIG. 6 is a partial enlarged view of an example of an electrical path in a cross section in the state where the shutter mechanism has been closed, in the embodiments.

FIG. 7 is a partial enlarged view of an example of a cross section of a groove on an electrically conductive surface and an electrically conductive member, in the embodiments.

FIG. 8 is a diagram illustrating an example of a relation between a diameter and a deformation amount of the electrically conductive member.

FIG. 9 is a diagram illustrating an example of a relation between a diameter and a deformation amount of the electrically conductive member.

FIG. 10 is a diagram illustrating an example of a plasma processing system in an alternative example.

### DESCRIPTION OF EMBODIMENT

Embodiments of a substrate processing apparatus disclosed will hereinafter be described in detail on the basis of the drawings. The disclosed techniques are not to be limited by the following embodiments.

The present disclosure provides a substrate processing apparatus that enables a uniform electrical path to be secured between a valve body and a chamber while providing redundancy for temperature changes and machine differences.

In recent years, there is a demand for transferring in-chamber parts and other parts larger than the outer diameter of a substrate through the opening of a chamber, and there is thus a demand for the opening to be enlarged and the shutter's valve body to be increased in size. However, increasing the size of the shutter's valve body increases the area of contact with the electrically conductive upper member (for example, a deposition shield) provided along the inner wall of the chamber's upper portion, to which the valve body is pressed against, and sufficient electrical continuity between the valve body and the upper member may be unable to be achieved. Furthermore, sufficient electrical continuity between a lower portion of the valve body and the baffle plate may be unable to be achieved due to temperature changes and machine differences. For example, when at least one of the temperature of the baffle plate and the temperature of the deposition shield rises, thermal expansion occurs, and an upper portion of the valve member is pressed against the upper member, the face-to-face distance between the electrically conductive contact surface and the bottom surface of the groove in the electrically conductive member increases at the lower portion of the valve body, resulting in a reduction of the compression allowance, and the contact pressure between the valve body and the baffle plate may thereby become insufficient, leading to unstable electrical continuity. To address this, achieving electrical continuity by contacting and sliding the baffle plate, connected to the lower portion of the valve body, with and against a substrate support unit in the diametrical direction of the chamber by means of a leaf spring may be considered. However, in this case, deformation of the leaf spring and generation of particles caused by the sliding pose problems. Improving durability, reducing the generation of particles, providing redundancy for temperature changes and machine differences, and securing a uniform electrical path between the valve body and the upper member are thus hoped for.

### Configuration of Substrate Processing System

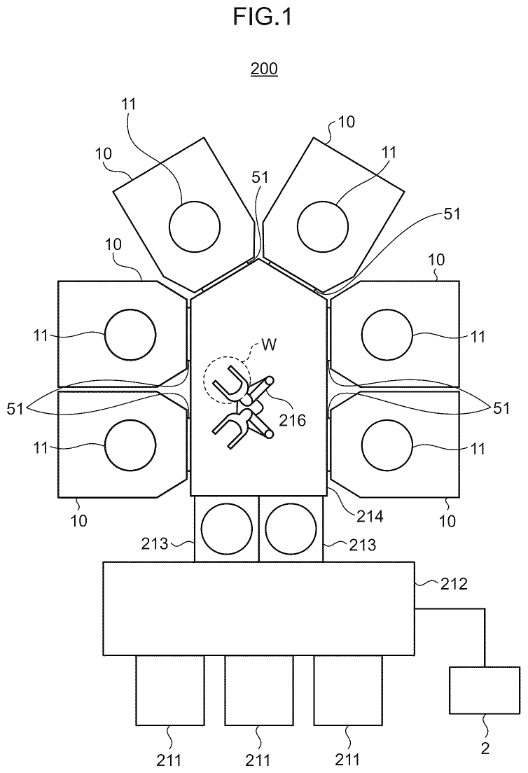

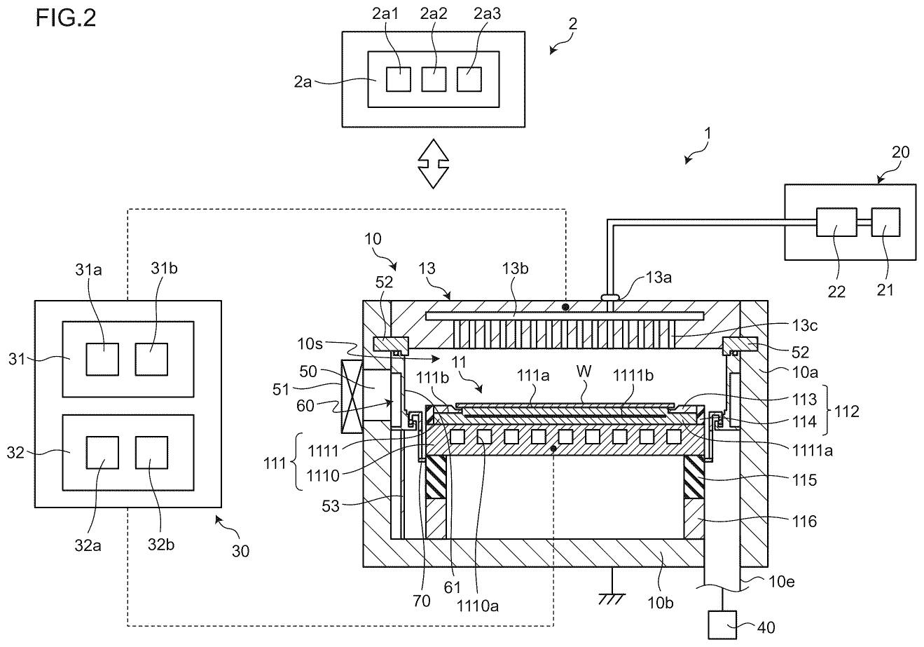

An example of a configuration of a substrate processing system will be described hereinafter. FIG. 1 is a schematic plan view of an example of a substrate processing system in an embodiment of the present disclosure. A substrate processing system 200 has load ports 211, a loader chamber 212, load lock chambers 213, and a substrate transfer chamber 214. Furthermore, the substrate processing system 200 has a controller 2 and substrate processing chambers 10. The controller 2 and the substrate processing chambers 10 in FIG. 1 respectively correspond to a controller 2 and a plasma processing chamber 10 of a plasma processing apparatus 1 illustrated in FIG. 2 described later.

The load ports 211 have, placed thereon, for example, a FOUP (not illustrated in the drawings), which is a carrier accommodating a predetermined number of substrates W with a diameter of ø300 mm. Three load ports 211 are provided, for example. The loader chamber 212 is adjacent to the load ports 211 and carries substrates W into or out from the FOUPs. The interior of the loader chamber 212 is in an atmospheric pressure atmosphere, and a transfer robot (not illustrated in the drawings) for transferring the substrates W has been arranged inside the loader chamber 212. The loader chamber 212 transfers the substrates W between the FOUPs placed on the load ports 211 and the load lock chambers 213.

The load lock chambers 213 are substrate delivery chambers and two load lock chambers 213 are arranged opposite to the load ports 211, with the loader chamber 212 interposed between the load lock chambers 213 and the loader chambers 212. The load lock chambers 213 are configured such that their interior is able to be selectively switched to a vacuum atmosphere or an atmospheric pressure atmosphere. The interior of the load lock chambers 213 is in the atmospheric pressure atmosphere when the load lock chambers 213 are in communication with the loader chamber 212, and is in the vacuum atmosphere when the load lock chambers 213 are in communication with the substrate transfer chamber 214. The load lock chambers 213 serve as intermediate transfer chambers for transferring the substrates W between the loader chamber 212 and the substrate transfer chamber 214. The load lock chambers 213 are an example of load lock modules (LLMs).

For example, the substrate transfer chamber 214 has a pentagonal shape in a plan view and is arranged opposite to the loader chamber 212, with the load lock chambers 213 interposed between the substrate transfer chamber 214 and the loader chamber 212. Six substrate processing chambers 10 are arranged radially around the substrate transfer chamber 214 and are each connected to the substrate transfer chamber 214. The interior of the substrate transfer chamber 214 is constantly maintained at a predetermined degree of vacuum, and a transfer robot 216 that transfers the substrates W has been arranged in the substrate transfer chamber 214. The transfer robot 216 transfers the substrates W between the substrate processing chambers 10 and between the substrate processing chambers 10 and the load lock chambers 213. The substrate transfer chamber 214 is an example of a vacuum transfer module (VTM).

As described later, the controller 2 is implemented by, for example, a computer 2a. The controller 2 may include a processing unit 2a1, a storage 2a2, and a communication interface 2a3, described later. The processing unit 2a1 may be configured to read a program from the storage 2a2, execute the program read, and thereby control operation of each component of the substrate processing system 200. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

In the substrate processing system 200, the substrate processing chambers 10 and the substrate transfer chamber 214 are connected to each other via gate valves 51. The gate valves 51 control communication between the substrate processing chambers 10 and the substrate transfer chamber 214. The interior of each of the substrate processing chambers 10 is maintained in a vacuum at a predetermined degree of vacuum, a substrate W is placed on a substrate support unit 11 arranged inside each of the substrate processing chambers 10, and the substrate W is subjected to a predetermined plasma process, for example, a plasma etching process therein. The substrate processing chambers 10 are an example of process modules (PMs). Furthermore, the substrate processing chambers 10 will hereinafter be also referred to as plasma processing chambers 10.

FIG. 2 is a diagram illustrating an example of a plasma processing system in an embodiment of the present disclosure. As illustrated in FIG. 2, the plasma processing system includes a capacitively coupled plasma processing apparatus 1 and a controller 2. The capacitively coupled plasma processing apparatus 1 includes a plasma processing chamber 10, a gas supply unit 20, a power source 30, and an exhaust system 40. Furthermore, the plasma processing apparatus 1 includes a substrate support unit 11 and a gas introduction unit. The gas introduction unit is configured to introduce at least one processing gas into the plasma processing chamber 10. The gas introduction unit includes a shower head 13. The substrate support unit 11 is arranged inside the plasma processing chamber 10. The shower head 13 is arranged above the substrate support unit 11. In an embodiment, the shower head 13 forms at least part of the ceiling of the plasma processing chamber 10. The plasma processing chamber 10 has a plasma processing space 10s defined by the shower head 13, a sidewall 10a of the plasma processing chamber 10, and the substrate support unit 11. The plasma processing chamber 10 has at least one gas supply port for supplying at least one processing gas to the plasma processing space 10s, and at least one gas discharge port for discharging gas from the plasma processing space 10s. The plasma processing chamber 10 is grounded. The shower head 13 and the substrate support unit 11 are electrically insulated from a housing of the plasma processing chamber 10.

The substrate support unit 11 includes a main body unit 111 and a ring assembly 112. The main body unit 111 has a central region 111a for supporting a substrate W, and a ring-shaped region 111b for supporting the ring assembly 112. A wafer is an example of the substrate W. The ring-shaped region 111b of the main body unit 111 surrounds the central region 111a of the main body unit 111 in a plan view. The substrate W is arranged on the central region 111a of the main body unit 111, and the ring assembly 112 is arranged on the ring-shaped region 111b of the main body unit 111 so as to surround the substrate W that is on the central region 111a of the main body unit 111. Therefore, the central region 111a is also called a substrate support surface for supporting the substrate W, and the ring-shaped region 111b is also called a ring support surface for supporting the ring assembly 112. Furthermore, the substrate support unit 11 is installed on a bottom portion 10b of the plasma processing chamber 10 via a base plate 115 and a support member 116. The base plate 115 and the support member 116 are formed of an electrically conductive material, such as, for example, aluminum, similarly to the plasma processing chamber 10.

In an embodiment, the main body unit 111 includes a base 1110 and an electrostatic chuck 1111. The base 1110 includes an electrically conductive member. The electrically conductive member of the base 1110 may function as a lower electrode. The electrostatic chuck 1111 is arranged on the base 1110. The electrostatic chuck 1111 includes a ceramic member 1111a and an electrostatic electrode 1111b arranged inside the ceramic member 1111a. The ceramic member 1111a has the central region 111a. In an embodiment, the ceramic member 1111a also has the ring-shaped region 111b. Another member surrounding the electrostatic chuck 1111, such as a ring-shaped electrostatic chuck or a ring-shaped insulating member, may have the ring-shaped region 111b. In this case, the ring assembly 112 may be arranged on the ring-shaped electrostatic chuck or ring-shaped insulating member, or may be arranged on both the electrostatic chuck 1111 and the ring-shaped insulating member. Furthermore, at least one RF/DC electrode coupled to a radio frequency (RF) power source 31 and/or a direct current (DC) power source 32, which will be described later, may be arranged in the ceramic member 1111a. In this case, the at least one RF/DC electrode functions as a lower electrode. In a case where a later described bias RF signal and/or a later described DC signal is supplied to the at least one RF/DC electrode, that RF/DC electrode is also called a bias electrode. The electrically conductive member of the base 1110 and the at least one RF/DC electrode may function as a plurality of lower electrodes. Furthermore, the electrostatic electrode 1111b may function as a lower electrode. Therefore, the substrate support unit 11 includes at least one lower electrode.

The ring assembly 112 includes one or more ring-shaped members. In an embodiment, the one or more ring-shaped members include one or more edge rings 113 and at least one cover ring 114. The edge ring 113 is formed of an electrically conductive material or an insulating material, and the cover ring 114 is formed of an insulating material. That is, the substrate support unit 11 has the edge ring 113 positioned around an upper surface of the substrate support unit 11. Furthermore, the substrate support unit 11 further has the cover ring 114 positioned around the edge ring 113.

Furthermore, the substrate support unit 11 may include a temperature adjustment module configured to adjust at least one of the electrostatic chuck 1111, the ring assembly 112, and a substrate, to a target temperature. The temperature adjustment module may include a heater, a heat transfer medium, a channel 1110a, or a combination thereof. Heat transfer fluid, such as brine or gas, flows through the channel 1110a. In an embodiment, the channel 1110a is formed in the base 1110, and one or more heaters are arranged in the ceramic member 1111a of the electrostatic chuck 1111. Furthermore, the substrate support unit 11 may include a heat transfer gas supply unit configured to supply heat transfer gas to a gap between a reverse face of the substrate W and the central region 111a.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Furthermore, the shower head 13 includes at least one upper electrode. The gas introduction unit may include, in addition to the shower head 13, one or more side gas injectors (SGIs) attached to one or more openings formed in the sidewall 10a.

The gas supply unit 20 may include at least one gas source 21 and at least one flow controller 22. In an embodiment, the gas supply unit 20 is configured to supply at least one processing gas to the shower head 13 from the gas source 21 corresponding to each of the at least one processing gas via the flow controller 22 corresponding to each of the at least one processing gas. Each flow controller 22 may include, for example, a mass flow controller or a pressure-controlled flow controller. Furthermore, the gas supply unit 20 may include one or more flow modulation devices that modulate or pulse flow of the at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thereby formed from at least one processing gas supplied to the plasma processing space 10s. Therefore, the RF power source 31 may function as at least part of a plasma generation unit configured to generate plasma from one or more processing gases in the plasma processing chamber 10. Furthermore, by supply of a bias RF signal to the at least one lower electrode, a bias potential is generated on the substrate W and ion components in the plasma formed are able to be drawn into the substrate W.

In an embodiment, the RF power source 31 includes a first RF generation unit 31a and a second RF generation unit 31b. The first RF generation unit 31a is coupled to at least one lower electrode and/or at least one upper electrode via at least one impedance matching circuit and is configured to generate a source RF signal (source RF power) for plasma generation. In an embodiment, the source RF signal has a frequency in a range of 10 MHz to 150 MHz. In an embodiment, the first RF generation unit 31a may be configured to generate a plurality of source RF signals having different frequencies. The generated one or more source RF signals are supplied to the at least one lower electrode and/or the at least one upper electrode.

The second RF generation unit 31b is coupled to at least one lower electrode via at least one impedance matching circuit and is configured to generate a bias RF signal (bias RF power). The bias RF signal may have a frequency that is the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generation unit 31b may be configured to generate a plurality of bias RF signals having different frequencies. The generated one or more bias RF signals are supplied to the at least one lower electrode. Furthermore, in various embodiments, at least one of the source RF signal and the bias RF signal may be pulsed.

Furthermore, the power source 30 may include the DC power source 32 coupled to the plasma processing chamber 10. The DC power source 32 includes a first DC generation unit 32a and a second DC generation unit 32b. In an embodiment, the first DC generation unit 32a is connected to at least one lower electrode and is configured to generate a first DC signal. The first bias DC signal generated is applied to the at least one lower electrode. In an embodiment, the second DC generation unit 32b is connected to at least one upper electrode and is configured to generate a second DC signal. The second DC signal generated is applied to the at least one upper electrode.

In various embodiments, at least one of the first and second DC signals may be pulsed. In this case, a sequence of voltage pulses is applied to the at least one lower electrode and/or the at least one upper electrode. The voltage pulses may have a rectangular pulse form, a trapezoidal pulse form, a triangular pulse form, or a combination thereof. In an embodiment, a waveform generation unit for generating a sequence of voltage pulses from a DC signal is connected between the first DC generation unit 32a and the at least one lower electrode. Therefore, the first DC generation unit 32a and the waveform generation unit form a voltage pulse generation unit. In a case where the second DC generation unit 32b and the waveform generation unit form the voltage pulse generation unit, the voltage pulse generation unit is connected to the at least one upper electrode. The voltage pulses may have a positive polarity or a negative polarity. Furthermore, the sequence of voltage pulses may include one or more positive voltage pulses and one or more negative voltage pulses, in one cycle. The first and second DC generation units 32a and 32b may be provided in addition to the RF power source 31, and the first DC generation unit 32a may be provided instead of the second RF generation unit 31b.

The exhaust system 40 may be connected to, for example, a gas discharge port 10e provided in the bottom portion of the plasma processing chamber 10. The exhaust system 40 may include a pressure regulating valve and a vacuum pump. Pressure in the plasma processing space 10s is regulated by the pressure regulating valve. The vacuum pump may include a turbo molecular pump, a dry pump, or a combination thereof.

An opening 50 that is mainly for carrying in and carrying out the substrate W is provided in and a gate valve 51 to open and close the opening 50 is arranged on the sidewall 10a of the plasma processing chamber 10. Furthermore, the opening 50 has a dimension enabling at least the edge ring 113 to pass therethrough. The opening 50 may have a dimension that enables the cover ring 114 to be transferred therethrough. Furthermore, the plasma processing chamber 10 may have at least one opening 50. That is, the plasma processing chamber 10 may have a plurality of openings 50.

A deposition shield 52 has been detachably provided along an inner wall of the plasma processing chamber 10 in the plasma processing chamber 10. The deposition shield 52 is an example of an upper member. The deposition shield 52 is provided above the opening 50 of the plasma processing chamber 10. A lower portion of the deposition shield 52 closes the opening 50 by contacting an upper portion of a valve body 61 of a shutter mechanism 60 described later. The deposition shield 52 may be formed by, for example, coating an aluminum material with a ceramic, such as yttrium oxide. The lower portion of the deposition shield 52 has been coated with an electrically conductive material, such as, for example, stainless steel or a nickel alloy, so as to be electrically continuous with the valve body 61 that the lower portion of the deposition shield 52 contacts. Furthermore, in a case where the opening 50 has been closed, a lower portion of the valve body 61 is in contact with an end portion of a baffle plate 70 described later.

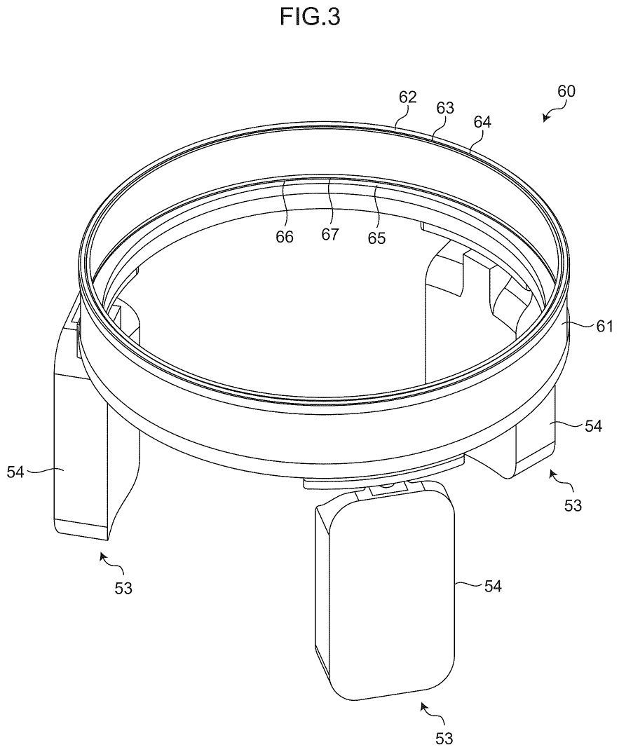

The substrate W is carried in and carried out by the gate valve 51 being opened or closed. However, because the gate valve 51 has been arranged outside the plasma processing chamber 10 (toward the transfer chamber (the substrate transfer chamber 214)), a space formed in the opening 50 protrudes toward the transfer chamber. Therefore, plasma generated in the plasma processing chamber 10 is diffused to that space, uniformity of the plasma is deteriorated, and a seal member of the gate valve 51 is deteriorated. Similarly, plasma generated in the plasma processing chamber 10 is diffused to a space toward the gas discharge port 10e, and the uniformity of the plasma is deteriorated. Accordingly, the deposition shield 52 is shut off from a sidewall of the main body unit 111 by the shutter mechanism 60 and the baffle plate 70, and the opening 50 and the gas discharge port 10e of the plasma processing chamber 10 are thereby shut off from the plasma processing space 10s. Furthermore, a lifting/lowering mechanism 53 that drives the shutter mechanism 60 is arranged below the valve body 61, for example. The lifting/lowering mechanism 53 has a rod connected to the valve body 61, and a drive unit 54 (see FIG. 3) that moves the rod up and down by means of an air cylinder or a motor, for example. The shutter mechanism 60 is driven up and down by the lifting/lowering mechanism 53 to open or close the opening 50. Furthermore, a plurality of lifting/lowering mechanisms 53, for example, three lifting/lowering mechanisms 53 are preferably installed to balance the vertical movement of the valve body 61. The shutter mechanism 60 may include the lifting/lowering mechanisms 53.

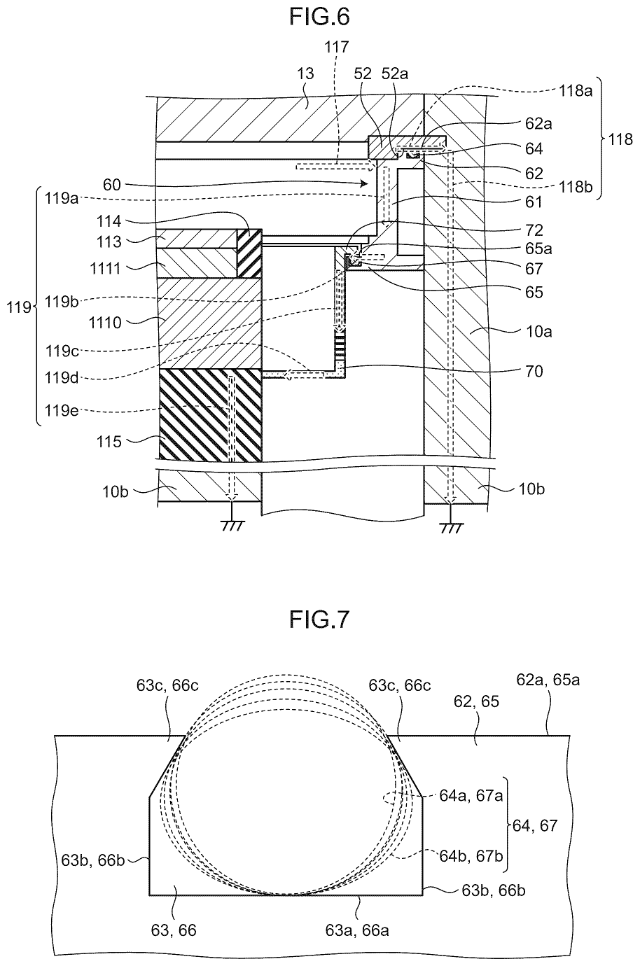

The baffle plate 70 is provided between the substrate support unit 11 and the shutter mechanism 60. A lower end portion (one of end portions) of the baffle plate 70 is fixed (see FIG. 6) to the base plate 115 positioned below the substrate support unit 11, for example. A cross section of the baffle plate 70 has an L shape, an upper end portion of the L-shape is folded outward, and an end face of that end portion is in the direction of a reverse face of the baffle plate 70. A through hole 71 described later is provided on a vertical wall surface of the baffle plate 70, to enable exhaust from the plasma processing space 10s.

The controller 2 processes computer-executable commands for causing the plasma processing apparatus 1 to execute various processes described in the present disclosure. The controller 2 may be configured to control each element of the plasma processing apparatus 1 to execute various processes described herein. In an embodiment, part or all of the controller 2 may be included in the plasma processing apparatus 1. The controller 2 may include the processing unit 2a1, the storage 2a2, and the communication interface 2a3. The controller 2 is implemented by, for example, the computer 2a. The processing unit 2a1 may be configured to read a program from the storage 2a2, execute the program read, and thereby perform various control operations. The program may be stored in the storage 2a2 beforehand, or may be obtained via a medium when needed. The obtained program is stored in the storage 2a2, and read and executed from the storage 2a2 by the processing unit 2a1. The medium may be any of various storage media that are able to be read by the computer 2a, or may be a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line, such as a local area network (LAN).

### Details of Shutter Mechanism 60

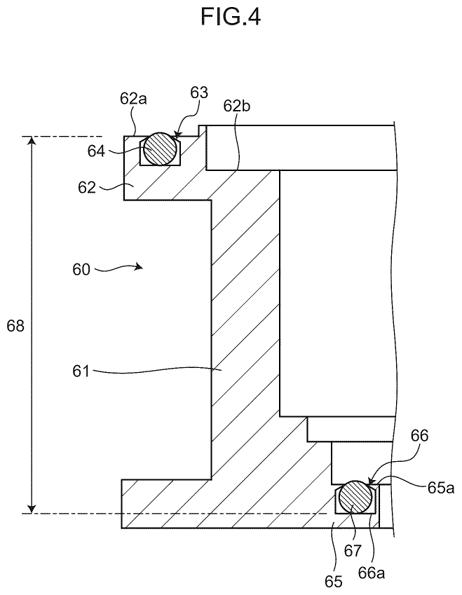

FIG. 3 is a perspective view of an example of a shutter mechanism in the embodiments. FIG. 4 is a partial enlarged view of an example of a cross section of a valve body of the shutter mechanism in the embodiments. As illustrated in FIG. 3 and FIG. 4, the shutter mechanism 60 has the valve body 61 having a length that is half of the inner circumference of the plasma processing chamber 10 or longer, and two or more lifting/lowering mechanisms 53 (including the drive unit 54) for lifting and lowering the valve body 61. FIG. 3 is in a state where the drive units 54 of the lifting/lowering mechanisms 53 are visible. A valve body 61 having a ring shape along the inner circumference of the plasma processing chamber 10 may be used as the valve body 61, as illustrated in FIG. 3, for example. The valve body 61 also has functions of a deposition shield.

For example, the valve body 61 is formed using an aluminum material and has a cross section that is approximately I-shaped, with flanges on the top and bottom. A surface of the valve body 61 has been coated with, for example, yttrium oxide. Furthermore, in a case where a cylindrical part made of quartz or silicon is used as a member facing plasma, in the valve body 61, a surface of a member (an aluminum material, for example) that does not come into direct contact with the plasma may be subjected to treatment, such as anodizing treatment. The valve body 61 has an upper portion 62 that comes into contact with the deposition shield 52 when the opening 50 is closed, and a stepped portion 65 that comes into contact with the baffle plate 70, the stepped portion 65 being the lower portion. A groove 63 that is arc-shaped is provided along the circle of the valve body 61, on an upper surface 62a of the upper portion 62. In a case where the valve body 61 is ring-shaped, the groove 63 is provided in a ring shape (circular shape). An electrically conductive member 64 for achieving electrical continuity with the deposition shield 52 is provided in the groove 63. The electrically conductive member 64 is provided in an arc shape or a ring shape correspondingly to the arc shape or ring shape of the groove 63. A groove 66 that is arc-shaped is provided along the circle of the valve body 61, on an upper surface 65a of the stepped portion 65. In a case where the valve body 61 is ring-shaped, the groove 66 is provided in a ring shape (circular shape). An electrically conductive member 67 for achieving electrical continuity with the baffle plate 70 is provided in the groove 66. The electrically conductive member 67 is provided in an arc shape or a ring shape correspondingly to the arc shape or ring shape of the groove 66. The electrically conductive members 64 and 67 are also called conductance bands or spirals and are electrically conductive elastic members. Stainless steel or a nickel alloy, for example, may be used for the electrically conductive members 64 and 67. The electrically conductive members 64 and 67 are each formed by, for example, spirally winding a strip-shaped member. Furthermore, a diagonally wound coil spring with a U-shaped jacket may be used, for example, as the electrically conductive member 64 or 67. That is, the electrically conductive members 64 and 67 are brought into a compressed state when the valve body 61 comes into contact with the deposition shield 52 and the baffle plate 70. The groove 63 provided on the upper surface 62a of the upper portion 62 is an example of a second groove, and the electrically conductive member 64 arranged therein is an example of a second electrically conductive member. The groove 66 provided on the upper surface 65a of the stepped portion 65 is an example of a first groove, and the electrically conductive member 67 arranged therein is an example of a first electrically conductive member. The upper surface 62a of the upper portion 62 is an example of the second electrically conductive surface, and the upper surface 65a of the stepped portion 65 is an example of the first electrically conductive surface.

The lifting/lowering mechanisms 53 each have a rod, and the rod is fixed and connected to the lower portion of the valve body 61 with a screw, for example. The lifting/lowering mechanisms 53 each move the rod up and down by means of an air cylinder or a motor of the drive unit 54, for example. In a case where air cylinders are used for the lifting/lowering mechanisms 53, the flow of dry air supplied to the lifting/lowering mechanisms 53 is controlled to be equal to one another. In the example of FIG. 3, the drive units 54 of the three lifting/lowering mechanisms 53 are arranged at equal intervals of 120 degrees. By moving up and down at the same timings and velocities, the lifting/lowering mechanisms 53 allow the valve body 61 to be lifted and lowered without the valve body 61 being bent or tilted. Furthermore, for example, in a case where the valve body 61 has a semicircular shape along the inner circumference of the plasma processing chamber 10, providing the lifting/lowering mechanisms 53 at both of end portions of the valve body 61 enables the valve body 61 to be lifted and lowered similarly.

In the shutter mechanism 60, the opening 50 is closed by the valve body 61 being pushed up by the lifting/lowering mechanisms 53 and the opening 50 is opened by the valve body 61 being pulled down by the lifting/lowering mechanisms 53. In a state where the valve body 61 has closed the opening 50, the electrically conductive members 64 and 67 arranged in the upper portion 62 and the stepped portion 65 of the valve body 61 respectively come into contact with the deposition shield 52 and the baffle plate 70, and the valve body 61 is thereby electrically connected to the deposition shield 52 and the baffle plate 70 via the electrically conductive members 64 and 67. The deposition shield 52 and the baffle plate 70 are in contact with the plasma processing chamber 10, which has been grounded. Therefore, in a state where the opening 50 has been closed, the valve body 61 is grounded via the deposition shield 52 and the baffle plate 70.

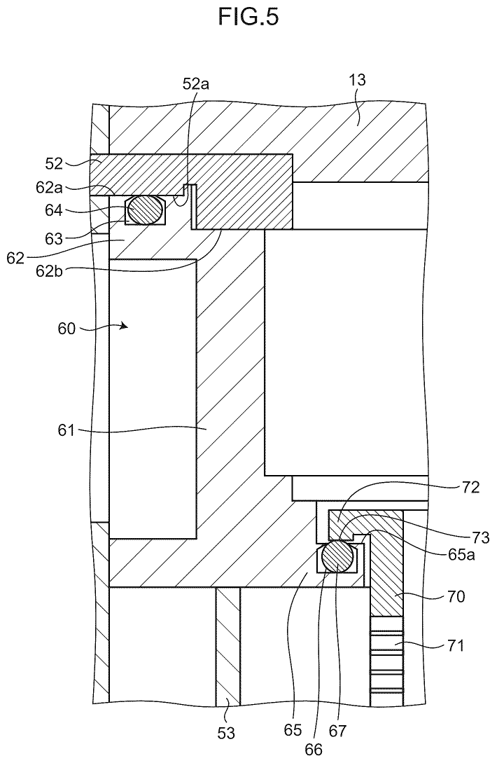

A state of contact between the shutter mechanism 60 and the deposition shield 52 and between the shutter mechanism 60 and the baffle plate 70, in a state where the shutter mechanism 60 has been closed will be described next by use of FIG. 5 and FIG. 6. FIG. 5 is a partial enlarged view of an example of a cross section in a state where the shutter mechanism has been closed in the embodiments. As illustrated in FIG. 5, the upper portion 62 of the valve body 61 of the shutter mechanism 60 is brought into contact with the deposition shield 52 provided near the shower head 13 above the plasma processing chamber 10, and the electrically conductive member 64 is thereby brought into the compressed state. Electrical continuity between the valve body 61 and the deposition shield 52 is achieved in this state. An electrically conductive member not illustrated in the drawings may be provided between the deposition shield 52 and an upper surface 62b of the upper portion 62. Furthermore, in a case where the valve body 61 is lifted, the upper surface 62a of the upper portion 62 comes into contact with the deposition shield 52, simultaneously with the upper surface 62b or before the upper surface 62b.

An upper end portion 72 of the L shape of the cross section of the baffle plate 70 is folded outward and an end face 73 thereof is in the direction of the reverse face of the baffle plate 70 (downward in the plasma processing chamber 10). The through hole 71 is provided on the vertical wall surface of the baffle plate 70. The through hole 71 connects the plasma processing space 10s with the space toward the gas discharge port 10e. The end face 73 is brought into contact with the stepped portion 65 of the valve body 61. The contact between the end face 73 and the stepped portion 65 includes contact between the end face 73 and the electrically conductive member 67 at the stepped portion 65. In a state where the upper surface 62a of the upper portion 62 of the valve body 61 has been brought into contact with a lower surface 52a of the deposition shield 52, the electrically conductive member 67 provided in the groove 66 of the stepped portion 65 is in the compressed state. In this state, the upper surface 65a of the stepped portion 65 and the end face 73 may be not in surface-to-surface contact. That is, the valve body 61 and the baffle plate 70 are in a state where electrical continuity has been achieved by the electrically conductive member 67 that has been compressed. That is, the upper surface 62a of the upper portion 62 of the valve body 61 serves as a positioning surface (a mechanical stop surface) that determines a raising position of the valve body 61, the upper surface 62a being a surface that comes into contact with the lower surface 52a of the deposition shield 52. Therefore, the gap between the upper surface 65a of the stepped portion 65 and the end face 73 varies due to accumulated dimensional tolerances and thermal expansion of the components. The variation in the gap between the upper surface 65a of the stepped portion 65 and the end face 73 is absorbed by the amount of compression of the electrically conductive member 67. That is, the amount of compression of the electrically conductive member 67 provides redundancy for temperature changes and machine differences. The upper surface 65a of the stepped portion 65 is an example of a first electrically conductive surface and the upper surface 62a of the upper portion 62 is an example of a second electrically conductive surface. Furthermore, the groove 66 is an example of a first groove and the groove 63 is an example of a second groove. That is, the end face 73 of the baffle plate 70 constitutes the reverse face of the baffle plate 70 that the first electrically conductive surface (upper surface 65a) contacts in the vertical direction when the valve body 61 is lifted to close the opening 50. The lower surface 52a of the deposition shield 52 constitutes the surface of the upper member that the second electrically conductive surface (upper surface 62a) contacts in the vertical direction when the valve body 61 is lifted to close the opening 50.

Furthermore, the surface pressure of the positioning surface including the lower surface 52a of the deposition shield 52 and the upper surface 62a of the upper portion 62 is preferably a pressure equal to or higher than a specific pressure (for example, 30 kPa or higher). Heat transfer between the deposition shield 52 and the valve body 61 is thereby able to be stabilized. Furthermore, because the valve body 61 is pressed against the deposition shield 52 by the pressure equal to or higher than the specific pressure, the electrically conductive member 64 is compressed and elastically deformed and the electrical continuity between the deposition shield 52 and the valve body 61 is also able to be stabilized.

FIG. 6 is a partial enlarged view of an example of an electrical path in a cross section in the state where the shutter mechanism has been closed in the embodiments. As illustrated in FIG. 6, in the state where the shutter mechanism 60 has been closed, the electrically conductive member 64 has been compressed, and electrical continuity is achieved between the valve body 61 and the deposition shield 52. Furthermore, the electrically conductive member 67 has been compressed and electrical continuity is achieved between the valve body 61 and the baffle plate 70. An opposite end portion of the baffle plate 70 is fixed to the base plate 115 and electrical continuity is achieved between the baffle plate 70 and the base plate 115, the opposite end portion being opposite to the end portion 72. Electrical continuity between the base plate 115 and the bottom portion 10b of the plasma processing chamber 10 is achieved via the support member 116 (see FIG. 2). The lower portion (the lower surface 52a) of the deposition shield 52, on the other hand, has been coated with an electrically conductive material, and the electrically conductive material achieves electrical continuity between the lower portion (the lower surface 52a) of the deposition shield 52 and the sidewall 10a of the plasma processing chamber 10. That is, the valve body 61 is grounded via two routes that are: a route 118 through the upper portion 62, from a route 117; and a route 119 through the stepped portion 65, from the route 117. An electrical path, via which the valve body 61 is grounded through the upper portion 62, the electrically conductive member 64, the deposition shield 52, the sidewall 10a, and the bottom portion 10b, as indicated by arrows 118a and 118b, is formed by the route 118. An electrical path, via which the valve body 61 is grounded through the stepped portion 65, the electrically conductive member 67, the baffle plate 70, the base plate 115, the support member 116, and the bottom portion 10b, as indicated by arrows 119a to 119e, is formed by the route 119. The sidewall 10a and the shower head 13 are electrically insulated from each other, and the base plate 115 and the base 1110 are electrically insulated from each other.

That is, in a case where the valve body 61 is lifted and the opening 50 is closed, the electrical path (the route 119) through the electrically conductive member 67, the baffle plate 70, and the base plate 115 is formed between the first electrically conductive surface (the upper surface 65a) and the plasma processing chamber 10 (the sidewall 10a and the bottom portion 10b). Furthermore, in the case where the valve body 61 is lifted and the opening 50 is closed, the electrical path (the route 118) through the electrically conductive member 64 and the upper member (deposition shield 52) is formed between the second electrically conductive surface (upper surface 62a) and the plasma processing chamber 10 (the sidewall 10a and the bottom portion 10b). In other words, with respect to the first electrically conductive surface (upper surface 65a) and the second electrically conductive surface (upper surface 62a), in a case where the valve body 61 is lifted and the opening 50 is closed, an electrical path through the respective first electrically conductive members 67 and 64, the baffle plate 70, the base plate 115, the plasma processing chamber 10, and the upper member (the deposition shield 52) is formed. The electric potential of the valve body 61 is thereby able to be stabilized.

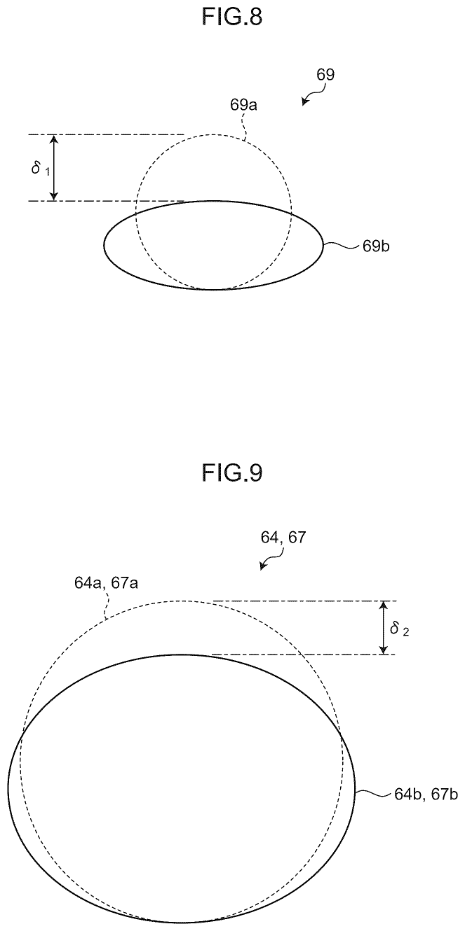

Cross-sectional shapes of the grooves 63 and 66 and elastic deformation of the electrically conductive members 64 and 67 will be described next by use of FIG. 7 to FIG. 9. FIG. 7 is a partial enlarged view of an example of a cross section of a groove on an electrically conductive surface and an electrically conductive member, in the embodiments. FIG. 8 and FIG. 9 are diagrams each illustrating an example of a relation between a diameter and a deformation amount of the electrically conductive member. As illustrated in FIG. 7, protruding portions 63c and 66c have been provided on upper portions of side surfaces 63b and 66b, such that widths of openings of the grooves 63 and 66 are narrower than widths of bottom surfaces 63a and 66a of the grooves 63 and 66, the openings being on the upper surfaces 62a and 65a of the upper portion 62 and the stepped portion 65. The protruding portions 63c and 66c serve as so-called “retaining lips” that prevent the electrically conductive members 64 and 67, arranged in the grooves 63 and 66, from coming out. That is, the cross sections of the electrically conductive members 64 and 67 in a state where the shutter mechanism 60 is open are circular, and the widths of the openings of the grooves 63 and 66 on the upper surface 62a of the upper portion 62 and the upper surface 65a of the stepped portion 65 are respectively smaller than the diameters of the cross sections of the electrically conductive members 64 and 67 respectively arranged therein. Furthermore, depths of the grooves 63 and 66 are respectively smaller than the diameters of the cross sections of the electrically conductive members 64 and 67 respectively arranged therein. Furthermore, widths of the grooves 63 and 66 on the bottom surface 63a or 66a between the side surfaces 63b or between the side surfaces 66b are respectively larger than the diameters of the cross sections of the electrically conductive members 64 and 67 respectively arranged therein. In FIG. 7, broken lines represent part of trajectories of the elastic deformation of the electrically conductive members 64 and 67, as electrically conductive members 64a and 67a and electrically conductive members 64b and 67b.

That is, the widthwise cross section of the opening of each of the grooves 63 and 66 (the cross section illustrated in FIG. 7) may include: the bottom surface 63a or 66a parallel to the upper surface 62a of the upper portion 62 or the upper surface 65a of the stepped portion 65; and the side surfaces 63b or 66b orthogonal to the bottom surface 63a or 66a. The side surfaces 63b or 66b may be shaped differently, for example, in a tapered shape such that the cross section of the groove 63 or 66 becomes narrower toward the upper surface 62a or 65a, as long as a space is able to be secured in the groove 63 or 66 so that the electrically conductive member 64 or 67 does not come into contact with the side surfaces 63b or 66b even if the electrically conductive member 64 or 67 is deformed in the groove 63 or 66. Furthermore, the protruding portions 63c and 66c respectively protruding inward in the grooves 63 or 66 may be respectively included at connections between the upper surface 62a of the upper portion 62 and the side surfaces 63b or at connections between the upper surface 65a of the stepped portion 65 and the side surfaces 66b, of the grooves 63 and 66. The upper surface 62a of the upper portion 62 is an example of the second electrically conductive surface, and the upper surface 65a of the stepped portion 65 is an example of the first electrically conductive surface.

In the state where the shutter mechanism 60 is open, as represented by the electrically conductive members 64a and 67a, the electrically conductive members 64 and 67 have not been compressed and are in contact with the protruding portions 63c or 66c and the bottom surface 63a or 66a. That is, the electrically conductive members 64 and 67 are freely deformable without receiving any reaction force from the side surfaces 63b or 66b. Furthermore, in the state where the shutter mechanism 60 has been closed, as represented by the electrically conductive members 64b or 67b, the electrically conductive members 64 and 67 are compressed and deformed, but do not come into contact with at least one of the side surfaces 63b or 66b and do not receive any reaction force from the side surfaces 63b or 66b. For example, even if the electrically conductive member 64 or 67 moves in the groove 63 or 66 and comes into contact with one of the side surfaces 63b or 66b, the electrically conductive member 64 or 67 does not come into contact with the other one of the side surfaces 63b or 66b and is thus able to allow any reaction force to escape. FIG. 7 illustrates a state where the upper portion of the electrically conductive member 64b or 67b extends above the upper surface 62a of the upper portion 62 or the upper surface 65a of the stepped portion 65, but the embodiments are not to be limited to this state. For example, even if the electrically conductive members 64 and 67 are compressed to a state where the upper surface 62a of the upper portion 62 comes into contact with the lower surface 52a of the deposition shield 52, the electrically conductive members 64 and 67 do not contact the side surfaces 63b or 66b and do not receive any reaction force from the side surfaces 63b or 66b. That is, in a case where the opening 50 has been closed, the electrically conductive members 64 and 67 are elastically deformed and do not come into contact with the side surfaces 63b or 66b. Therefore, reaction force from the electrically conductive members 64 and 67 is reduced and required thrust for the drive units 54 of the lifting/lowering mechanisms 53 is thus able to be reduced.

Furthermore, the larger the diameter of the electrically conductive member 64 or 67, the smaller the strain and the smaller the resulting reaction force. For example, it is assumed that an electrically conductive member 69 illustrated in FIG. 8 is an electrically conductive member having a cross section with a diameter smaller than those of the electrically conductive members 64 and 67 and is deformed by a deformation amount δ₁ from an electrically conductive member 69a in an uncompressed state to an electrically conductive member 69b in a compressed state. In contrast, it is assumed that the electrically conductive member 64 or 67 illustrated in FIG. 9 is deformed by a deformation amount δ₂ from the electrically conductive member 64a or 67a in an uncompressed state to the electrically conductive member 64b or 67b in a compressed state. In a case where the same amount of deformation (amount of compression) is to be applied, that is, in a case where the deformation amount δ₁ equals the deformation amount δ₂, the electrically conductive member 64b or 67b undergoes less strain than the electrically conductive member 69b. In a case where the electrically conductive member 64 or 67 is made of the same material and has the same thickness as the electrically conductive member 69b, the reaction force is considered to be proportional to the strain according to Hooke's law. For example, in a case where a certain deformation amount is desired to be applied, halving the diameter of an electrically conductive member made of the same material and having the same thickness doubles the reaction force. That is, the reaction force from the electrically conductive member 64 or 67 is smaller than that from the electrically conductive member 69, whose cross-sectional diameter is smaller than that of the electrically conductive member 64 or 67.

As described above, in the valve body 61, the gap between the upper surface 65a of the stepped portion 65 and the end face 73 varies due to accumulated dimensional tolerances and thermal expansion of the components. The range of deformation of the electrically conductive member 64 or 67 is now discussed, in consideration of such variation and the deformation amount of the electrically conductive member 64 or 67. As a basis for this discussion, a section 68 from the upper surface 62a of the upper portion 62 to the bottom surface 66a of the groove 66, illustrated in FIG. 4, is used.

Firstly, for example, it is assumed that for the electrically conductive members 64 and 67, it has been experimentally confirmed that stable electrical continuity is able to be achieved if the deformation amount is α% or more relative to a diameter D of the electrically conductive member 64 or 67. A deformation amount (compression amount) t (mm) at which stable electrical continuity is able to be achieved in this case can be expressed by Equation 1 below. That is, from Equation 1, a deformation amount t of D×α/100 (mm) or more will be sufficient for the electrically conductive members 64 and 67. For example, if α is set to 7.2, in a case where the diameter of the electrically conductive member 64 or 67 is 6.95 mm, a deformation amount t of 0.5 mm or more will be sufficient. In this case, a reaction force Fᵤ of the electrically conductive member 64 can be expressed by Equation 2 below and a reaction force F_{L} of the electrically conductive member 67 can be expressed by Equation 3 below. The reaction force Fᵤ is an example of a second reaction force and the reaction force F_{L} is an example of a first reaction force.

t=D×α/100 (1)

Fᵤ=kLᵤ(t+σᵤ) (2)

F_{L}=kL_{L}(t+σ_{L}+δ) (3)

Herein, Fᵤ denotes the reaction force (N) of the electrically conductive member 64 and F_{L} denotes the reaction force (N) of the electrically conductive member 67. Furthermore, k represents the reaction force coefficient (N/mm²) with respect to the deformation amount t of the electrically conductive member 64 or 67. Lᵤ denotes the length (mm) of the electrically conductive member 64 in its circumferential direction, and L_{L} denotes the length (mm) of the electrically conductive member 67 in its circumferential direction. Furthermore, σᵤ denotes the tolerance (mm) for the upper surface 62a of the upper portion 62, and σ_{L} denotes the tolerance (mm) for the bottom surface 66a of the groove 66 of the stepped portion 65. Furthermore, δ denotes the amount of thermal expansion (mm).

Furthermore, as to the reaction forces of the electrically conductive members 64 and 67, the thrust from the lifting/lowering mechanisms 53 is required to be larger than the total of the reaction forces of the electrically conductive members 64 and 67 because the upper surface 62a of the upper portion 62 is positioned by the lower surface 52a of the deposition shield 52. This relation can be expressed by Equation 4 below.

Fₛₕᵤₜₜₑᵣ>Fᵤ+F_{L}+M×g (4)

Herein, Fₛₕᵤₜₜₑᵣ denotes the total thrust from the lifting/lowering mechanisms 53, M denotes the deadweight (kg) of the valve body 61, and g denotes the gravitational acceleration (m/s²). In Equations 1 to 4, the upper limit value of the amount of thermal expansion δ under ideal conditions where the tolerances are all ±0 is considered to be 1.62% of the section 68. That is, the upper limit of the deformation amount of the electrically conductive member 67 arranged in the stepped portion 65 is preferably equal to or less than the total of: a deformation amount that is α% (7.2%) or more of the diameter D; and a value that is 1.62% or less of the section 68. That is, the upper limit of the deformation amount of the electrically conductive member 67 is, for example, t (0.5) mm+a value that is 1.62% of the section 68, and the lower limit of the deformation amount of the electrically conductive member 67 is, for example, t (0.5) mm. The upper limit of the deformation amount of the electrically conductive member 67 is a value at which the upper surface 62a of the upper portion 62 does not come into contact with the lower surface 52a of the deposition shield 52 and positioning is unable to be implemented in a case where it is assumed that the electrically conductive member 67 is going to be compressed by an amount larger than the upper limit. Furthermore, the lower limit of the deformation amount of the electrically conductive member 67 is a value at which electrical stability is unable to be achieved in a case where it is assumed that the deformation amount of the electrically conductive member 67 is going to be less than the lower limit. Furthermore, the above mentioned 1.62% of the section 68 for the upper limit of the deformation amount of the electrically conductive member 67 is an example of a case where the plasma processing chamber 10 accommodates a substrate W with a diameter of 300 mm, for example. Therefore, the percentage value corresponding to section 68 will change in a case where the length of the shutter mechanism 60 in the circumferential direction, the length being based on the size of the plasma processing chamber 10, the material that the electrically conductive member 67 is made of, the processing temperature in the plasma processing chamber 10, or the dimension of any of parts of the valve body 61 is changed.

Furthermore, the diameter of the electrically conductive member 67 and the diameter of the electrically conductive member 64 may have different values, according to the width (the width of the cross section) of the stepped portion 65 in the diametrical direction. For example, the diameter of the electrically conductive member 67 may be a value equal to or larger than 50% of the diameter of the electrically conductive member 64. In this case, the width of the groove 66 is also changed according to the diameter of the electrically conductive member 67. The electrically conductive member 67 is an example of a first electrically conductive member, and the electrically conductive member 64 is an example of a second electrically conductive member.

As described above, in the plasma processing apparatus 1 according to the embodiments, even if the temperature of the valve body 61 and the baffle plate 70 rises and thermal expansion occurs, contact pressure between the upper surface 65a of the stepped portion 65 of the valve body 61 and the end face 73 of the end portion 72 of the baffle plate 70 is able to be maintained and stable electrical continuity is achieved. That is, the plasma processing apparatus 1 enables redundancy for temperature changes and machine differences to be provided and uniform electrical paths to be secured between the valve body 61 and the deposition shield 52 (the upper member) and between the valve body 61 and the baffle plate 70. That is, in the plasma processing apparatus 1, the trade-off relation between the deformation amount and the reduction of reaction force for the electrically conductive members 64 and 67 is able to be resolved and the elasticity of the electrically conductive members 64 and 67 is able to be maintained. Furthermore, generation of particles is able to be reduced because the valve body 61 and the baffle plate 70 do not slide in the plasma processing apparatus 1. Furthermore, durability of the plasma processing apparatus 1 is able to be improved because a leaf spring is not used in the shutter mechanism 60. Furthermore, because the direction in which the electrically conductive member 64 comes into contact with the deposition shield 52 and the direction in which the electrically conductive member 67 comes into contact with the baffle plate 70 are the same as the direction in which the valve body 61 moves, uniform contact in the circumferential direction is able to be achieved without reliance on centering of the valve body 61 in relation to the substrate support unit 11.

### Alternative Example

In the above described embodiments, the opening 50 is provided toward the substrate transfer chamber 214 but a plurality of openings 50 that are a first opening toward the substrate transfer chamber 214 and a second opening toward the sidewall 10a opposite thereto in a plan view may be provided, and an embodiment in this case will be described as an alternative example. A plasma processing system in this alternative example is similar to that of the above described embodiment except for the opening 50 of the plasma processing chamber 10, and any redundant description of its components and operation will thus be omitted.

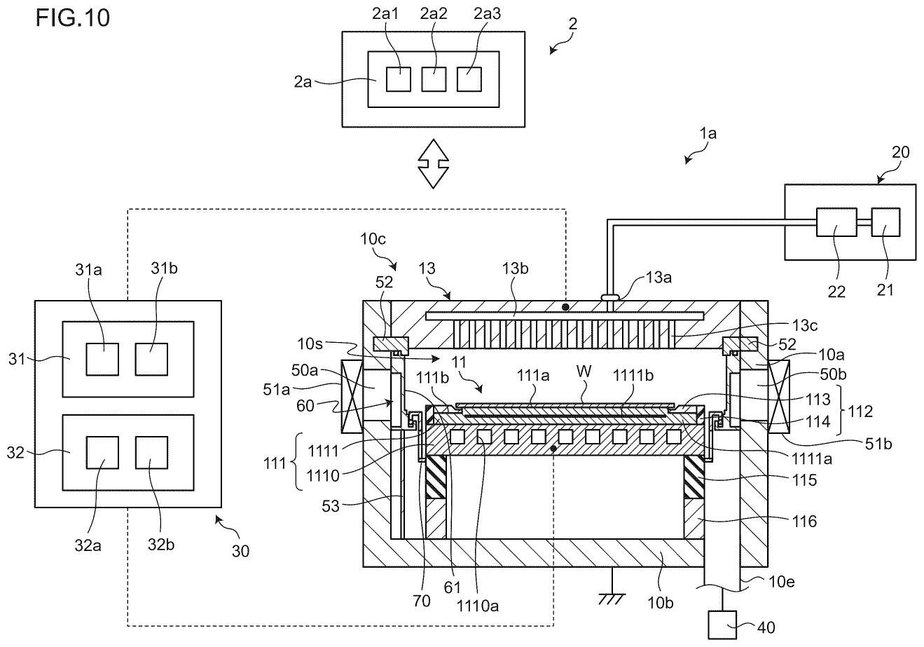

FIG. 10 is a diagram illustrating an example of the plasma processing system in the alternative example. As illustrated in FIG. 10, a plasma processing apparatus 1a in the alternative example has, instead of the plasma processing chamber 10 of the plasma processing apparatus 1 of the embodiments, a plasma processing chamber 10c.

A first opening 50a for mainly carrying in and carrying out a substrate W is provided in and a gate valve 51a to open and close the first opening 50a is arranged on a sidewall 10a of the plasma processing chamber 10c. Furthermore, for example, a second opening 50b is provided in and a gate valve 51b to open and close the second opening 50b is arranged on a sidewall 10a opposite to the first opening 50a in a plan view. Furthermore, similarly to the above described embodiments, the first opening 50a and the second opening 50b are able to be closed by a valve body 61 of a shutter mechanism 60.

The first opening 50a has a dimension that allows at least an edge ring 113 to pass therethrough. That is, the first opening 50a allows the substrate W and the edge ring 113 to be carried in and carried out therethrough. The second opening 50b has a dimension that allows at least a cover ring 114 to be transferred therethrough. That is, the second opening 50b allows the substrate W, the edge ring 113, and the cover ring 114 to be carried in and carried out therethrough. That is, the substrate W and the cover ring 114 may pass through different openings (the first opening 50a and the second opening 50b). For example, a transfer apparatus (not illustrated in the drawings) having another transfer chamber in a vacuum atmosphere is connected to the second opening 50b. When the gate valve 51b is opened, the other transfer chamber and a plasma processing space 10s are brought into communication with each other via the second opening 50b. That is, the transfer apparatus connected to the second opening 50b enables, for example, the cover ring 114 to be transferred from the plasma processing space 10s to its transfer chamber (the other transfer chamber). The first opening 50a and the second opening 50b are an example of the plurality of openings 50. Furthermore, similarly to the above described embodiments, for example, the first opening 50a and the second opening 50b may be provided in two stages in a vertical direction on the sidewall 10a toward a substrate transfer chamber 214, or may each be provided at any position on the sidewall 10a, as long as the first opening 50a and the second opening 50b are able to be closed by the valve body 61.

That is, the openings 50 include the first opening 50a and the second opening 50b, the first opening 50a has the dimension allowing at least the edge ring 113 to pass therethrough, and the second opening 50b has the dimension allowing at least the cover ring 114 to be transferred therethrough. The cover ring 114 is thereby able to be carried in and carried out through a route different from that of the substrate W.

As described above, according to the embodiments, the substrate processing apparatus (the plasma processing apparatus 1) has: a chamber (the plasma processing chamber 10) that is cylindrical and is configured to have at least one opening 50; the shutter mechanism 60 configured to open and close the opening 50; the substrate support unit 11 configured to support the substrate W; and the baffle plate 70 configured to be provided between the substrate support unit 11 and the shutter mechanism 60. The shutter mechanism 60 includes: the valve body 61 having a length that is half of the inner circumference of the chamber or longer; the first electrically conductive surface (upper surface 65a) that is provided on the lower portion (the stepped portion 65) of the valve body 61 and comes into contact with the reverse face (the end face 73) of the baffle plate 70; the second electrically conductive surface (the upper surface 62a) that is provided on the upper portion 62 of the valve body 61 and comes into contact with the upper member (the deposition shield 52) that is provided along the inner wall of the upper portion of the chamber, the upper member being electrically conductive; the electrically conductive members 67 and 64 that are arc-shaped or ring-shaped and are respectively arranged in the grooves 66 and 63 that are respectively provided on the first electrically conductive surface and the second electrically conductive surface, the grooves being arc-shaped or ring-shaped; and two or more lifting/lowering mechanisms 53 that are connected to the lower portion of the valve body 61 and lift and lower the valve body 61. In a case where the valve body 61 is lifted and the opening 50 is closed, the first electrically conductive surface comes into contact with the reverse face of the baffle plate 70 in the vertical direction and becomes electrically continuous with the reverse face of the baffle plate 70 by means of the electrically conductive member 67. In the case where the valve body 61 is lifted and the opening 50 is closed, the second electrically conductive surface comes into contact with the upper member in the vertical direction and becomes electrically continuous with the upper member by means of the electrically conductive member 64. As a result, redundancy for temperature changes and machine differences is able to be provided and a uniform electrical path between the valve body 61 and the upper member is able to be secured.

Furthermore, the electrically conductive members 67 and 64 according to the embodiments have cross sections that are circular. Furthermore, the openings of the grooves 66 and 63 on the first electrically conductive surface and the second electrically conductive surface respectively have widths that are smaller than the diameters of the cross sections of the electrically conductive members 67 and 64 respectively arranged therein. As a result, the electrically conductive members 67 and 64 are able to be prevented from coming out of the grooves 66 and 63.

Furthermore, according to the embodiments, depths of the grooves 66 and 63 are respectively smaller than the diameters of the cross sections of the electrically conductive members 67 and 64 respectively arranged therein. As a result, uniform electrical paths are able to be secured between the valve body 61 and the deposition shield 52 (the upper member) and between the valve body 61 and the baffle plate 70.

Furthermore, according to the embodiments, the widthwise cross sections of the openings of the grooves 66 and 63 each include the bottom surface 66a or 63a parallel to the first electrically conductive surface or second electrically conductive surface, and the side surfaces 66b or 63b orthogonal to the bottom surface 66a or 63a, and each include the protruding portions 66c or 63c protruding inward in the groove 66 or 63, the protruding portions 66c or 63c being at the connections in the groove 66 or 63, the connections being between the first electrically conductive surface or second electrically conductive surface and the side surfaces 66b or 63b. As a result, the electrically conductive members 67 and 64 are able to be prevented from coming out of the groove 66 or 63.

Furthermore, according to the embodiments, the grooves 66 and 63 respectively have widths larger than the diameters of the cross sections of the electrically conductive members 67 and 64 respectively arranged therein, the widths each being on the bottom surface 66a or 63a between the side surfaces 66b or 63b. As a result, the reaction force received by the electrically conductive members 67 and 64 is able to be reduced.

Furthermore, according to the embodiments, in a case where the opening 50 has been closed, the electrically conductive members 67 and 64 each undergo elastic deformation and each do not come into contact with at least one of the side surfaces 66b or 63b. As a result, the reaction force received by the electrically conductive members 67 and 64 is able to be reduced.

Furthermore, according to the embodiments, the electrically conductive members 67 and 64 include the first electrically conductive member (the electrically conductive member 67) arranged in the first groove (the groove 66) provided on the first electrically conductive surface, and the second electrically conductive member (the electrically conductive member 64) arranged in the second groove (the groove 63) provided on the second electrically conductive surface. Furthermore, the cross section of the first electrically conductive member has a diameter at a value that is 50% or more of the diameter of the cross section of the second electrically conductive member. As a result, the degree of freedom in arrangement of the electrically conductive member 67 is able to be improved.

Furthermore, according to the embodiments, the electrically conductive members 67 and 64 include the first electrically conductive member (the electrically conductive member 67) arranged in the first groove (the groove 66) provided on the first electrically conductive surface, and the second electrically conductive member (the electrically conductive member 64) arranged in the second groove (the groove 63) provided on the second electrically conductive surface. Furthermore, in a case where the opening 50 is closed, the first electrically conductive member and the second electrically conductive member undergo elastic deformation, and the upper limit of the deformation amount of the first electrically conductive member is a value larger than the upper limit of the deformation amount of the second electrically conductive member. As a result, uniform electrical paths are able to be secured between the valve body 61 and the deposition shield 52 (the upper member) and between the valve body 61 and the baffle plate 70.

Furthermore, according to the embodiments, the plurality of lifting/lowering mechanisms 53 are capable of outputting, as a total value, thrust larger than the total of: a first reaction force (the reaction force F_{L}) from the elastic deformation of the first electrically conductive member; a second reaction force (the reaction force Fᵤ) from the elastic deformation of the second electrically conductive member; and the deadweight of the valve body 61. As a result, the valve body 61 is able to be pressed against the deposition shield 52 with adequate pressure.

Furthermore, according to the embodiments, the valve body 61 is ring-shaped. Furthermore, the electrically conductive members 67 and 64 are respectively arranged in the grooves 66 and 63 that are ring-shaped and that are respectively provided over the entire circumference of the first electrically conductive surface and the second electrically conductive surface. As a result, stability of contact pressure and electrical continuity between the valve body 61 and the deposition shield 52 and between the valve body 61 and the baffle plate 70 are able to be maintained.

Furthermore, according to the embodiments, one of end portions of the baffle plate 70 is connected to the base plate 115 positioned below the substrate support unit 11. Furthermore, in a case where the valve body 61 is lifted and the opening 50 is closed, an electrical path through the electrically conductive member 67, the baffle plate 70, and the base plate 115 is formed between the first electrically conductive surface and the chamber and an electrical path through the electrically conductive member 64 and the upper member is formed between the second electrically conductive surface and the chamber. As a result, more uniform electrical paths between the valve body 61 and the baffle plate 70 and between the valve body 61 and the upper member are able to be secured.

Furthermore, according to the embodiments, the substrate support unit 11 has the edge ring 113 positioned around the upper surface of the substrate support unit, and the opening 50 has a dimension that allows at least the edge ring 113 to pass therethrough. As a result, nondurable parts including the edge ring 113 larger than the substrate W are able to be replaced via the opening 50. Furthermore, as compared to a case where the chamber is vented to the atmosphere for replacement of the edge ring 113, the downtime of the substrate processing apparatus is able to be shortened significantly.

Furthermore, according to the embodiments, the substrate W is transferred via the opening 50. As a result, nondurable parts including the edge ring 113 larger than the substrate W are able to be replaced via the opening 50.

Furthermore, according to the embodiments, the substrate support unit 11 further has the cover ring 114 positioned around the edge ring 113. The opening 50 has a dimension that allows the cover ring 114 to be transferred therethrough. As a result, nondurable parts including the cover ring 114 larger than the edge ring 113 are able to be replaced via the opening 50. Furthermore, as compared to a case where the chamber is vented to the atmosphere for replacement of the cover ring 114, the downtime of the substrate processing apparatus is able to be shortened significantly.

Furthermore, according to the embodiments and the alternative example, the openings 50 includes the first opening 50a and the second opening 50b. The first opening 50a has a dimension that allows at least the edge ring 113 to pass therethrough. The second opening 50b has a dimension that allows at least the cover ring 114 to be transferred therethrough. As a result, the cover ring 114 is able to be carried in and carried out through a route different from that of the substrate W.

Furthermore, according to the embodiments, the opening 50 is positioned toward the transfer chamber (the substrate transfer chamber 214). As a result, nondurable parts, such as the edge ring 113 and the cover ring 114 larger than the substrate W, are able to be replaced via the transfer chamber (the substrate transfer chamber 214).

Furthermore, according to the embodiments, the valve body 61 has a cross section that is approximately I-shaped. As a result, the valve body 61 is able to be reduced in weight.

Furthermore, according to the embodiments, the upper member has a portion coated with stainless steel or a nickel alloy. As a result, an electrical path via the upper member is able to be formed between the valve body 61 and the sidewall 10a of the chamber.

Furthermore, according to the embodiments, the electrically conductive members 67 and 64 are conductance bands, spirals, or coil springs. As a result, redundancy for temperature changes and machine differences is able to be provided and electrical continuity between the valve body 61 and the baffle plate 70 and between the valve body 61 and the upper member is able to be secured.

The embodiments disclosed this time are just examples in all aspects and should be considered to be nonrestrictive. Without departing from the appended claims and the spirit thereof, any omission, substitution, or modification may be made to the above-described embodiments in various forms.

Furthermore, with respect to the above described embodiments, the plasma processing apparatus 1 for processing, such as etching of substrates W using capacitively coupled plasma as a plasma source has been described as an example, but the disclosed techniques are not to be limited to this example. As long as the plasma processing apparatus 1 implements processing of substrates W using plasma, without being limited to capacitively coupled plasma, the plasma source used therein may be any plasma source, for example, inductively coupled plasma, microwave plasma, or magnetron plasma.

The present disclosure may also be configured as follows.
(1)

A substrate processing apparatus, wherein
the substrate processing apparatus comprises:
   a chamber that is cylindrical and is configured to have at least one opening;
   a shutter mechanism configured to open and close the opening;
   a substrate support configured to support a substrate; and
   a baffle plate configured to be provided between the substrate support and the shutter mechanism,
the shutter mechanism comprises:
   a valve body having a length that is half of the inner circumference of the chamber or longer;
   a first electrically conductive surface that is provided on a lower portion of the valve body and comes into contact with a reverse face of the baffle plate;
   a second electrically conductive surface that is provided on an upper portion of the valve body and comes into contact with an upper member that is provided along an inner wall of an upper portion of the chamber, the upper member being electrically conductive;
   electrically conductive members that are arc-shaped or ring-shaped and are respectively arranged in grooves that are respectively provided on the first electrically conductive surface and the second electrically conductive surface, the grooves being arc-shaped or ring-shaped; and
   two or more lifting/lowering mechanisms that are connected to the lower portion of the valve body and lift and lower the valve body,
in a case where the valve body is lifted and the opening is closed, the first electrically conductive surface comes into contact with the reverse face of the baffle plate in a vertical direction and becomes electrically continuous with the reverse face of the baffle plate by means of the electrically conductive members, and
in the case where the valve body is lifted and the opening is closed, the second electrically conductive surface comes into contact with the upper member in the vertical direction and becomes electrically continuous with the upper member by means of the electrically conductive members.
(2)

The substrate processing apparatus according to (1), wherein
the electrically conductive members have cross sections that are circular, and
openings of the grooves on the first electrically conductive surface and the second electrically conductive surface respectively have widths that are smaller than diameters of the cross sections of the electrically conductive members respectively arranged therein.
(3)

The substrate processing apparatus according to (2), wherein depths of the grooves are respectively smaller than the diameters of the cross sections of the electrically conductive members respectively arranged therein.
(4)

The substrate processing apparatus according to (2) or (3), wherein a widthwise cross section of the opening of each of the grooves includes a bottom surface parallel to the first electrically conductive surface or second electrically conductive surface, and side surfaces orthogonal to the bottom surface, and includes protruding portions protruding inward in the groove, the protruding portions being at connections in the groove, the connections being between the first electrically conductive surface or second electrically conductive surface and the side surfaces.
(5)

The substrate processing apparatus according to (4), wherein the grooves respectively have widths larger than the diameters of the cross sections of the electrically conductive members respectively arranged therein, the widths each being on the bottom surface between the side surfaces.
(6)

The substrate processing apparatus according to (5), wherein in a case where the opening has been closed, the electrically conductive members each undergo elastic deformation and each do not come into contact with at least one of the side surfaces.
(7)

The substrate processing apparatus according to any one of (2) to (6), wherein
the electrically conductive members include a first electrically conductive member arranged in a first groove provided on the first electrically conductive surface, and a second electrically conductive member arranged in a second groove provided on the second electrically conductive surface, and
a cross section of the first electrically conductive member has a diameter at a value that is 50% or more of the diameter of a cross section of the second electrically conductive member.
(8)

The substrate processing apparatus according to any one of (2) to (7), wherein
the electrically conductive members include a first electrically conductive member arranged in a first groove provided on the first electrically conductive surface and a second electrically conductive member arranged in a second groove provided on the second electrically conductive surface, and
in a case where the opening is closed, the first electrically conductive member and the second electrically conductive member undergo elastic deformation, and the upper limit of a deformation amount of the first electrically conductive member is a value larger than the upper limit of a deformation amount of the second electrically conductive member.
(9)

The substrate processing apparatus according to (8), wherein a plurality of the lifting/lowering mechanisms are capable of outputting, as a total value, thrust larger than the total of: a first reaction force from the elastic deformation of the first electrically conductive member; a second reaction force from the elastic deformation of the second electrically conductive member; and the deadweight of the valve body.
(10)

The substrate processing apparatus according to any one of (1) to (9), wherein
the valve body is ring-shaped, and
the electrically conductive members are respectively arranged in grooves that are ring-shaped and that are respectively provided over the entire circumferences of the first electrically conductive surface and the second electrically conductive surface.
(11)

The substrate processing apparatus according to any one of (1) to (10), wherein
one of end portions of the baffle plate is connected to a base plate positioned below the substrate support, and
in a case where the valve body is lifted and the opening is closed, an electrical path through the electrically conductive members, the baffle plate, and the base plate is formed between the first electrically conductive surface and the chamber, and an electrical path through the electrically conductive members and the upper member is formed between the second electrically conductive surface and the chamber.
(12)

The substrate processing apparatus according to any one of (1) to (11), wherein
the substrate support has an edge ring positioned around an upper surface of the substrate support, and the opening has a dimension that allows at least the edge ring to pass therethrough.
(13)

The substrate processing apparatus according to (12), wherein the substrate is transferred via the opening.
(14)

The substrate processing apparatus according to (12) or (13), wherein
the substrate support further has a cover ring positioned around the edge ring, and
the opening has a dimension that allows the cover ring to be transferred therethrough.
(15)

The substrate processing apparatus according to (14), wherein
the opening includes a first opening and a second opening,
the first opening has a dimension that allows at least the edge ring to pass therethrough, and
the second opening has a dimension that allows at least the cover ring to be transferred therethrough.
(16)

The substrate processing apparatus according to any one of (12) to (15), wherein the opening is positioned toward a transfer chamber.
(17)

The substrate processing apparatus according to any one of (1) to (16), wherein the valve body has a cross section that is approximately I-shaped.
(18)

The substrate processing apparatus according to any one of (1) to (17), wherein the upper member has a portion coated with stainless steel or a nickel alloy.
(19)

The substrate processing apparatus according to any one of (1) to (18), wherein the electrically conductive members are conductance bands, spirals, or coil springs.
(20)

A non-transitory computer-readable medium storing a program that, when executed by a processor of a controller configured to control a substrate processing apparatus, causes the controller to perform operations comprising:
controlling two or more lifting/lowering mechanisms connected to a lower portion of a valve body of a shutter mechanism to lift the valve body, the valve body comprising a first electrically conductive surface on the lower portion and a second electrically conductive surface on an upper portion, each of the first and second electrically conductive surfaces having an arc-shaped or ring-shaped groove in which an electrically conductive member is arranged, to close an opening of a cylindrical chamber of the substrate processing apparatus;
monitoring a position of the valve body to confirm that the first electrically conductive surface is in contact in a vertical direction with a reverse face of a baffle plate disposed between a substrate support and the shutter mechanism within the chamber, and that the second electrically conductive surface is in contact in the vertical direction with an electrically conductive upper member provided along an inner wall of an upper portion of the chamber, such that the electrically conductive members elastically compressed in the respective grooves establish electrical continuity between the valve body and the baffle plate and between the valve body and the upper member; and controlling, after confirming the opening is closed, a plasma generation process within the chamber.
(21)

A method of operating a substrate processing apparatus,
the substrate processing apparatus comprising:
   a cylindrical chamber having an opening;
   a shutter mechanism including two or more lifting/lowering mechanisms;
   a substrate support positioned within the chamber;
   a baffle plate between the substrate support and a shutter mechanism, and an electrically conductive upper member provided along an inner wall of an upper portion of the chamber, the method comprising:
      lifting, by two or more lifting/lowering mechanisms connected to a lower portion of a valve body of the shutter mechanism, the valve body to close the opening, each of the two or more lifting/lowering mechanisms including a rod connected to the valve body;
      contacting, in a vertical direction, a first electrically conductive surface provided on the lower portion of the valve body with a reverse face of the baffle plate, wherein a first electrically conductive member is arranged in an arc-shaped or ring-shaped groove provided on the first electrically conductive surface;
      contacting, in the vertical direction, a second electrically conductive surface provided on an upper portion of the valve body with the upper member, wherein a second electrically conductive member is arranged in an arc-shaped or ring-shaped groove provided on the second electrically conductive surface;
         elastically compressing the first and second electrically conductive members respectively arranged in the grooves of the first electrically conductive surface and the second electrically conductive surface to achieve electrical continuity between the valve body and the baffle plate and between the valve body and the upper member.

The present disclosure enables a uniform electrical path to be secured between a valve body and an upper member while providing redundancy for temperature changes and machine differences.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

What is claimed is

1. A substrate processing apparatus, comprising:
a chamber that is cylindrical and includes an opening;
a shutter mechanism opening and closing the opening;
a substrate support supporting a substrate; and
a baffle plate provided between the substrate support and the shutter mechanism, wherein
the shutter mechanism comprises:
a valve body having a length that is half of the inner circumference of the chamber or longer;
a first electrically conductive surface that is provided on a lower portion of the valve body and comes into contact with a reverse face of the baffle plate;
a second electrically conductive surface that is provided on an upper portion of the valve body and comes into contact with an upper member that is provided along an inner wall of an upper portion of the chamber, the upper member being electrically conductive;
electrically conductive members that are arc-shaped or ring-shaped and are respectively arranged in grooves that are respectively provided on the first electrically conductive surface and the second electrically conductive surface, the grooves being arc-shaped or ring-shaped; and
two or more lifting/lowering mechanisms that are connected to the lower portion of the valve body and lift and lower the valve body, each of the two or more lifting/lowering mechanisms including a rod connected to the valve body,
in a case where the valve body is lifted and the opening is closed, the first electrically conductive surface comes into contact with the reverse face of the baffle plate in a vertical direction and becomes electrically continuous with the reverse face of the baffle plate by means of the electrically conductive members, and
in the case where the valve body is lifted and the opening is closed, the second electrically conductive surface comes into contact with the upper member in the vertical direction and becomes electrically continuous with the upper member by means of the electrically conductive members.

2. The substrate processing apparatus according to claim 1, wherein
the electrically conductive members have cross sections that are circular, and
openings of the grooves on the first electrically conductive surface and the second electrically conductive surface respectively have widths that are smaller than diameters of the cross sections of the electrically conductive members respectively arranged therein.

3. The substrate processing apparatus according to claim 2, wherein depths of the grooves are respectively smaller than the diameters of the cross sections of the electrically conductive members respectively arranged therein.

4. The substrate processing apparatus according to claim 2, wherein a widthwise cross section of the opening of each of the grooves includes a bottom surface parallel to the first electrically conductive surface or second electrically conductive surface, and side surfaces orthogonal to the bottom surface, and includes protruding portions protruding inward in the groove, the protruding portions being at connections in the groove, the connections being between the first electrically conductive surface or second electrically conductive surface and the side surfaces.

5. The substrate processing apparatus according to claim 4, wherein the grooves respectively have widths larger than the diameters of the cross sections of the electrically conductive members respectively arranged therein, the widths each being on the bottom surface between the side surfaces.

6. The substrate processing apparatus according to claim 5, wherein in a case where the opening has been closed, the electrically conductive members each undergo elastic deformation and each do not come into contact with at least one of the side surfaces.

7. The substrate processing apparatus according to claim 2, wherein
the electrically conductive members include a first electrically conductive member arranged in a first groove provided on the first electrically conductive surface, and a second electrically conductive member arranged in a second groove provided on the second electrically conductive surface, and
a cross section of the first electrically conductive member has a diameter at a value that is 50% or more of the diameter of a cross section of the second electrically conductive member.

8. The substrate processing apparatus according to claim 2, wherein
the electrically conductive members include a first electrically conductive member arranged in a first groove provided on the first electrically conductive surface and a second electrically conductive member arranged in a second groove provided on the second electrically conductive surface, and
in a case where the opening is closed, the first electrically conductive member and the second electrically conductive member undergo elastic deformation, and an upper limit of a deformation amount of the first electrically conductive member is a value larger than the upper limit of a deformation amount of the second electrically conductive member.

9. The substrate processing apparatus according to claim 8, wherein a plurality of the two or more lifting/lowering mechanisms are capable of outputting, as a total value, thrust larger than the total of: a first reaction force from the elastic deformation of the first electrically conductive member; a second reaction force from the elastic deformation of the second electrically conductive member; and deadweight of the valve body.

10. The substrate processing apparatus according to claim 1, wherein
the valve body is ring-shaped, and
the electrically conductive members are respectively arranged in grooves that are ring-shaped and that are respectively provided over the entire circumferences of the first electrically conductive surface and the second electrically conductive surface.

11. The substrate processing apparatus according to claim 1, wherein
one of end portions of the baffle plate is connected to a base plate positioned below the substrate support, and
in a case where the valve body is lifted and the opening is closed, an electrical path through the electrically conductive members, the baffle plate, and the base plate is formed between the first electrically conductive surface and the chamber, and an electrical path through the electrically conductive members and the upper member is formed between the second electrically conductive surface and the chamber.

12. The substrate processing apparatus according to claim 1, wherein
the substrate support has an edge ring positioned around an upper surface of the substrate support, and the opening has a dimension that allows at least the edge ring to pass therethrough.

13. The substrate processing apparatus according to claim 12, wherein the substrate is transferred via the opening.

14. The substrate processing apparatus according to claim 12, wherein
the substrate support further has a cover ring positioned around the edge ring, and
the opening has a dimension that allows the cover ring to be transferred therethrough.

15. The substrate processing apparatus according to claim 14, wherein
the opening includes a first opening and a second opening,
the first opening has a dimension that allows at least the edge ring to pass therethrough, and
the second opening has a dimension that allows at least the cover ring to be transferred therethrough.

16. The substrate processing apparatus according to claim 1, wherein the valve body has a cross section that is approximately I-shaped.

17. The substrate processing apparatus according to claim 1, wherein the upper member has a portion coated with stainless steel or a nickel alloy.

18. The substrate processing apparatus according to claim 1, wherein the electrically conductive members are conductance bands, spirals, or coil springs.

19. A non-transitory computer-readable medium storing a program that, when executed by a processor of a controller configured to control a substrate processing apparatus, causes the controller to perform operations comprising:
controlling two or more lifting/lowering mechanisms connected to a lower portion of a valve body of a shutter mechanism to lift the valve body, the valve body comprising a first electrically conductive surface on the lower portion and a second electrically conductive surface on an upper portion, each of the first and second electrically conductive surfaces having an arc-shaped or ring-shaped groove in which an electrically conductive member is arranged, to close an opening of a cylindrical chamber of the substrate processing apparatus;
monitoring a position of the valve body to confirm that the first electrically conductive surface is in contact in a vertical direction with a reverse face of a baffle plate disposed between a substrate support and the shutter mechanism within the chamber, and that the second electrically conductive surface is in contact in the vertical direction with an electrically conductive upper member provided along an inner wall of an upper portion of the chamber, such that the electrically conductive members elastically compressed in the respective grooves establish electrical continuity between the valve body and the baffle plate and between the valve body and the upper member; and
controlling, after confirming the opening is closed, a plasma generation process within the chamber.

20. A method of operating a substrate processing apparatus,
the substrate processing apparatus comprising:
a cylindrical chamber having an opening;
a shutter mechanism including two or more lifting/lowering mechanisms;
a substrate support positioned within the chamber;
a baffle plate between the substrate support and a shutter mechanism, and an electrically conductive upper member provided along an inner wall of an upper portion of the chamber, the method comprising:
lifting, by two or more lifting/lowering mechanisms connected to a lower portion of a valve body of the shutter mechanism, the valve body to close the opening, each of the two or more lifting/lowering mechanisms including a rod connected to the valve body;
contacting, in a vertical direction, a first electrically conductive surface provided on the lower portion of the valve body with a reverse face of the baffle plate, wherein a first electrically conductive member is arranged in an arc-shaped or ring-shaped groove provided on the first electrically conductive surface;
contacting, in the vertical direction, a second electrically conductive surface provided on an upper portion of the valve body with the upper member, wherein a second electrically conductive member is arranged in an arc-shaped or ring-shaped groove provided on the second electrically conductive surface;
elastically compressing the first and second electrically conductive members respectively arranged in the grooves of the first electrically conductive surface and the second electrically conductive surface to achieve electrical continuity between the valve body and the baffle plate and between the valve body and the upper member.
